(19) United States
(12) Patent Application Publication
(10) Pub. No.: US 2022/0309329 A1
(43) Pub. Date: Sep. 29, 2022

(54) ARTIFICIAL NEURAL NETWORKS USING MAGNETORESISTIVE RANDOM-ACCESS MEMORY-BASED STOCHASTIC COMPUTING UNITS

(71) Applicant: Northwestern University, Evanston, IL (US)

(72) Inventor: Pedram Khalili Amiri, Chicago, IL (US)

(21) Appl. No.: 17/703,015

(22) Filed: Mar. 24, 2022

Related U.S. Application Data
(60) Provisional application No. 63/166,786, filed on Mar. 26, 2021.

(51) Int. Cl. G06N 3/063; G06N 3/04; G06F 7/58

(52) U.S. Cl. CPC G06N 3/063; G06N 3/0472; G06F 7/588

(57) ABSTRACT

A stochastic computing artificial neural network (SC-ANN) includes magnetic tunnel junction (MTJ) devices configured as true random number generators (TRNGs) to output stochastic bit-streams of random numbers for processing by input, hidden, and/or output nodes of the ANN. The processing may include multiplication by a weighting value corresponding to a respective numerical value from the stochastic bit-streams.

### CROSS REFERENCE TO RELATED APPLICATIONS

The present application claims the benefit of priority under 35 U.S.C. § 119 from U.S. Provisional Patent Application Ser. No. 63/166,786, entitled “Artificial Neural Networks Using Magnetoresistive Random-Access Memory-Based Stochastic Computing Units,” filed on Mar. 26, 2021, the disclosure of which is hereby incorporated by reference in its entirety for all purposes.

### STATEMENT OF FEDERALLY FUNDED RESEARCH OR SPONSORSHIP

This invention was made with government support under grant number IIP-1919109 awarded by the National Science Foundation. The government has certain rights in the invention.

### TECHNICAL FIELD

The present disclosure generally relates to artificial neural networks, and more specifically relates to artificial neural networks using magnetoresistive random-access memory-based stochastic computing units.

### BACKGROUND

Machine learning in portable systems and edge devices enables new applications in internet of things (IoT), autonomous driving, health, wearables, augmented/virtual reality, and more. Hardware implementations of Artificial Neural Networks (ANNs) using conventional binary arithmetic units have typically been used to implement machine learning.

### BRIEF DESCRIPTION OF DRAWINGS

The disclosure is better understood with reference to the following drawings and description. The elements in the figures are not necessarily to scale, emphasis instead being placed upon illustrating the principles of the disclosure. Moreover, in the figures, like-referenced numerals may designate to corresponding parts throughout the different views.

FIGS. 1A, 1B, and 1C illustrate exemplary magnetic tunnel junction (MTJ) device structure and physical mechanism.

FIGS. 2A, 2B, and 2C illustrate exemplary resistance as a function of external field for an MTJ measured under different DC voltages.

FIGS. 2D, 2E, and 2F illustrate exemplary MTJ resistance oscillations measured as a function of time, under a fixed external magnetic field and different bias voltages.

FIG. 3 illustrates exemplary probabilities of 1s and 0s (parallel and antiparallel states) generated by an MTJ under different bias voltages.

FIG. 4A illustrates exemplary stochastic multiplication using bipolar mapping within the [−1, 1] range.

FIG. 4B illustrates an exemplary approximate parallel counter (APC)-based neuron for stochastic dot product and activation functions.

FIG. 5 illustrates a structure of an exemplary Stochastic Computing Artificial Neural Network (SC-ANN) using pairs of MTJs for stochastic bit-stream generation.

FIG. 6A illustrates an exemplary confusion matrix of the results of an inference operation, using stochastic computing on 1024-bit long bit-streams.

FIG. 6B illustrates exemplary classification accuracy achieved on an SC-ANN using different stochastic bit-stream lengths.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### SUMMARY

An exemplary artificial neural network (ANN) includes magnetic tunnel junction (MTJ) devices, input nodes, hidden nodes, and an output node. The MTJ devices are configured as true random number generators (TRNGs) to output stochastic bit-streams of random numbers. The input nodes are configured to receive respective numerical values for processing by the ANN. At least one of the hidden nodes is in electrical communication with at least one of the input nodes to receive and output a sum of input values multiplied by corresponding first weighting values. The first weighting values correspond to respective numerical values from the stochastic bit-streams output by the MTJ devices. The output node is in electrical communication with at least one of the hidden nodes to receive and output a sum of hidden values multiplied by corresponding second weighting values.

Numerical values of the random numbers may be tuned by electrical current through the MTJ devices via spin-transfer torque.

The MTJ devices may include a Co/Pt multilayer-based synthetic antiferromagnetic (SAF) structure. The SAF structure may include a top electrode, a first ferromagnetic layer disposed below the top electrode, a tunnel barrier layer disposed below the first ferromagnetic layer, a second ferromagnetic layer disposed below the tunnel barrier layer, a coupling layer disposed below the second ferromagnetic layer, a SAF layer disposed below the coupling layer, and a bottom electrode disposed below the SAF layer. The top and bottom electrodes may each include an electrically conductive material. The first ferromagnetic layer may include a CoFeB material. The tunnel barrier layer may include a MgO material. The second ferromagnetic layer may include a CoFeB material.

At least one of the MTJ devices may be configured to introduce a random reshuffling mechanism.

The ANN may include a digitally controlled circuit configured to convert oscillations of the MTJ devices into the stochastic bit-streams.

The ANN may include a bias voltage setting circuit configured to set a bias voltage of the MTJ devices according to a training operation of the ANN.

The second weighting values may correspond to respective numerical values from the stochastic bit-streams output by the MTJ devices.

The input nodes may be configured to multiply respective input numerical values by input weighting values corresponding to respective numerical values from the stochastic bit-streams output by the MTJ devices.

The MTJ devices may include an electrically coupled pair of MTJ devices.

An exemplary ANN includes first, second, and third groups of MTJ devices configured as TRNGs to output first, second, and third stochastic bit-streams of random numbers, respectively. The exemplary ANN also includes input nodes, hidden nodes, and output nodes. The input nodes are configured to receive respective numerical values for processing by the ANN and multiply the respective numerical values by weighting values corresponding to respective numerical values from the first stochastic bit-streams. The hidden nodes are in electrical communication with at least one of the input nodes to receive and output a sum of input values multiplied by weighting values corresponding to respective numerical values from the second stochastic bit-streams. The output node is in electrical communication with at least one of the hidden nodes to receive and output a sum of hidden values multiplied by weighting values corresponding to a respective numerical values from the third stochastic bit-streams.

The ANN may include a bias voltage setting circuit configured to set a bias voltage of at least one of the MTJ devices according to a training operation of the ANN.

The ANN may include a digitally controlled circuit configured to convert oscillations of at least one of the MTJ devices into the respective stochastic bit-streams.

The numerical values of the random numbers may be tuned by electrical current through the MTJ devices via spin-transfer torque.

The MTJ devices may include a Co/Pt multilayer-based synthetic antiferromagnetic (SAF) structure. The SAF structure may include a top electrode, a first ferromagnetic layer disposed below the top electrode, a tunnel barrier layer disposed below the first ferromagnetic layer, a second ferromagnetic layer disposed below the tunnel barrier layer, a coupling layer disposed below the second ferromagnetic layer, a SAF layer disposed below the coupling layer, and a bottom electrode disposed below the SAF layer. The top and bottom electrodes may each include an electrically conductive material. The first ferromagnetic layer may include a CoFeB material. The tunnel barrier layer may include a MgO material. The second ferromagnetic layer may include a CoFeB material.

At least one of the MTJ devices may be configured to introduce a random reshuffling mechanism.

The MTJ devices may include an electrically coupled pair of MTJ devices.

An exemplary ANN includes MTJ devices configured as TRNGs to output stochastic bit-streams of random numbers, input nodes, and an output node. The input nodes are configured to process respective received numerical values for processing by the ANN. The output node is configured to process at least one intermediate value resulting from processing by at least one of the input nodes to generate and output a result value. The processing includes multiplication by a weighting value corresponding to a respective numerical value from the stochastic bit-streams.

The ANN may include hidden nodes communicatively connected between at least one of the input nodes and the output node. At least one of the hidden nodes may process values resulting from processing by at least one of the input nodes.

### DETAILED DESCRIPTION

The detailed description set forth below is intended as a description of various implementations and is not intended to represent the only implementations in which the subject technology may be practiced. As those skilled in the art would realize, the described implementations may be modified in various different ways, all without departing from the scope of the present disclosure. Accordingly, the drawings and description are to be regarded as illustrative in nature and not restrictive.

The disclosed technology provides compact and low-energy arithmetic hardware for hardware implementation of Artificial Neural Networks (ANNs). The arithmetic hardware may utilize stochastic computing (SC), where the probability of 1s and 0s in a randomly generated bit-stream is used to represent a decimal number. SC arithmetic hardware may implement basic arithmetic operations using far fewer logic gates than binary operations. Tunable true random number generators (TRNGs) may be used to realize SC in hardware. TRNGs may be inefficient for realization using existing CMOS technology. As disclosed herein, magnetic tunnel junctions (MTJs) may be used as TRNGs, the stochasticity of which may be tuned by an electric current via spin-transfer torque.

In an exemplary implementation of ANNs using SC units, stochastic bit-streams may be experimentally generated by a series of 50 nm perpendicular MTJs. The numerical value (1 to 0 ratio) of the bit-streams may be tuned by the electrical current through the MTJs via spin-transfer torque, with an ultralow current of <5 μA (=0.25 MA cm⁻²). The MTJ-based SC-ANN may achieve 95% accuracy for handwritten digit recognition on the MNIST database. MRAM-based SC-ANNs provide a promising solution for ultra-low-power machine learning in edge, mobile and IoT devices.

It should be understood from the above that the disclosed technology provides improvements including, but not limited to, reducing a size and an energy required by conventional binary artithmetic units compared to hardware implementations of ANNs using conventional binary arithmetic.

Machine learning in portable systems and edge devices may enable new applications in internet of things (IoT), autonomous driving, health, wearables, augmented/virtual reality (AR/VR), and other areas. Hardware implementations of Artificial Neural Networks (ANNs) using conventional binary arithmetic units may utilize larger area and energy than desired, due to massive multiplication and addition operations in an inference process. The large area and energy utilization may limit their efficient use in low-power portable systems, edge, and IoT devices. This may necessitate such IoT devices to frequently access the cloud or networked computing systems to hand-off computing tasks, which may lead to processing and communication delays as well as security risks.

Utilizing stochastic computing (SC) instead of conventional binary arithmetic units may facilitate compact and low-energy arithmetic hardware implementations of ANNs. Such implementations for IoTs, wearables, and other similar space- and/or power-constrained systems may facilitate the power and space requirements of ANNs to fit within the limited space and power budgets of these systems. SC may represent a decimal number using a probability of 1s or 0s in a randomly generated bit-stream. Using this representation, fewer logic gates may be used to implement basic arithmetic operations than are used to implement binary operations. Tunable true random number generators (TRNGs) may facilitate more efficient implementation of SC in hardware for ANNs than existing CMOS technology. A conventional 32-bit linear feedback shift register (LFSR) used for an RNG operation implemented in CMOS may utilize more than 1,000 transistors, for example.

A series of magnetoresistive random-access memory (MRAM) bits (e.g., magnetic tunnel junctions (MTJs)) may be configured to implement TRNGs. The TRNG operation may be based on thermal fluctuations at room temperature of an MTJ free layer. The stochasticity of these thermal fluctuations may be tuned by an ultralow current of <5 μA (0.25 MA cm⁻²) via spin-transfer torque (STT), for example, to generate tunable stochastic bit-streams representing a range of numbers from −1 to 1. An SC-based ANN utilizing MTJ-TRNGs and bit-streams that are experimentally generated from these MTJs to perform handwritten digit recognition on a MNIST database may demonstrate accuracy of 95% using a 1,024 bit stochastic bit-stream length, for example.

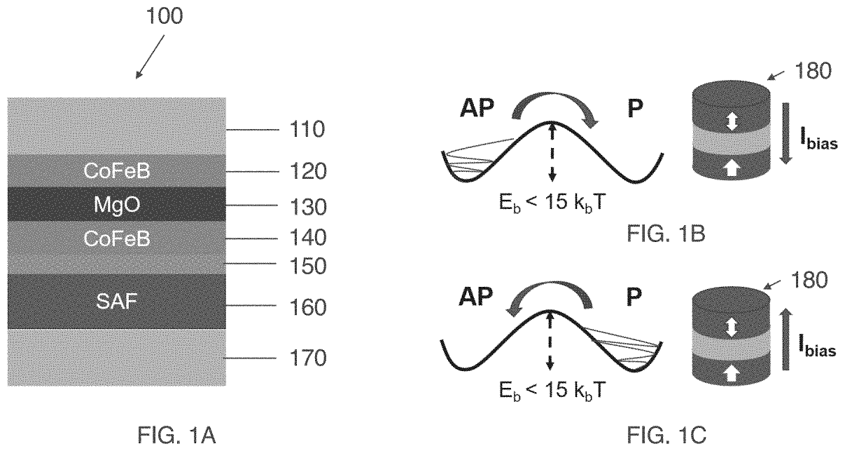

FIGS. 1A, 1B, and 1C illustrate exemplary magnetic tunnel junction (MTJ) device structure and physical mechanism. FIG. 1A illustrates an exemplary cross-section of an MTJ 100 having a bottom-pinned configuration with a Co/Pt multilayer-based synthetic antiferromagnetic (SAF) structure. A top electrode 110 may be constructed above a free layer 120. The free layer 120 may be composed of a CoFeB material. The free layer 120 may be constructed above a tunnel barrier 130 composed of a MgO material. The tunnel barrier 130 may be constructed above a reference layer 140 composed of a CoFeB material. The reference layer 140 may be constructed above a coupling layer 150. The coupling layer 150 may be constructed above a SAF layer 160. The SAF layer 160 may be constructed above a bottom electrode 170. FIG. 1B illustrates an exemplary energy diagram for an exemplary stochastic MTJ 180 under a downward moving bias current I_{bias}. FIG. 1C illustrates an exemplary energy diagram for the stochastic MTJ 180 under an upward moving bias current I_{bias}. A spin-transfer torque (STT) acting upon the MTJ free layer as illustrated in FIG. 1B may favor a parallel state P. In contrast, an STT acting upon the MTJ free layer as illustrated in FIG. 1C may favor an antiparallel state AP.

FIG. 1A illustrates an exemplary structure of a perpendicular MTJ 100. The MTJ 100 may include two ferromagnetic layers 120 and 140 separated by an oxide layer 130. Depending upon a direction of magnetization in the two ferromagnetic layers 120 and 140, the MTJ 100 may have a low-resistance parallel state (P) and a high-resistance antiparallel state (AP), resulting in a tunnel magnetoresistance (TMR) ratio of ˜130% and a parallel-state resistance-area (RA) product of ˜440 Ω-μm2. Exemplary MTJs 180 may be constructed to be circular and have a diameter of 50 nm.

The two states of an exemplary MTJ 180 may be separated by an energy barrier E_{b} which is proportional to the free layer volume and anisotropy. The retention time may be expressed as τ=τ₀exp (E_{b}/k_{B}T), where τ₀ is the characteristic attempt time (on the order of 1 ns), k_{B} is the Boltzmann constant, and T is temperature. For a large MTJ 180 where E_{b} is large enough, the retention time may be long, facilitating nonvolatile memory operation. The free layer thickness and anisotropy may be adjusted so that the retention time is reduced to ˜5 ms, corresponding to an energy barrier <16 k_{B}T. With a low energy barrier (e.g., <16 k_{B}T as illustrated in FIGS. 1B and 1C), the MTJ 180 may be stochastically switched between its two states at room temperature due to thermal fluctuations. In the presence of a current, one state or the other may be preferred by STT, as illustrated in FIGS. 1B and 1C.

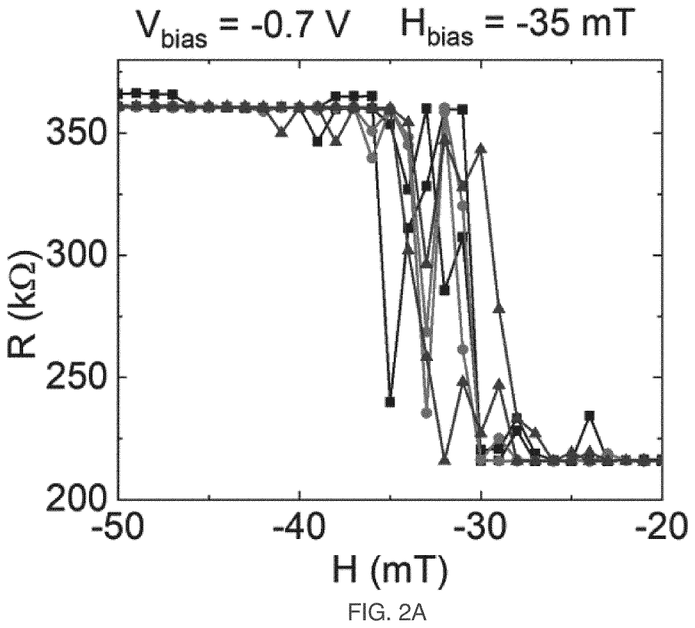

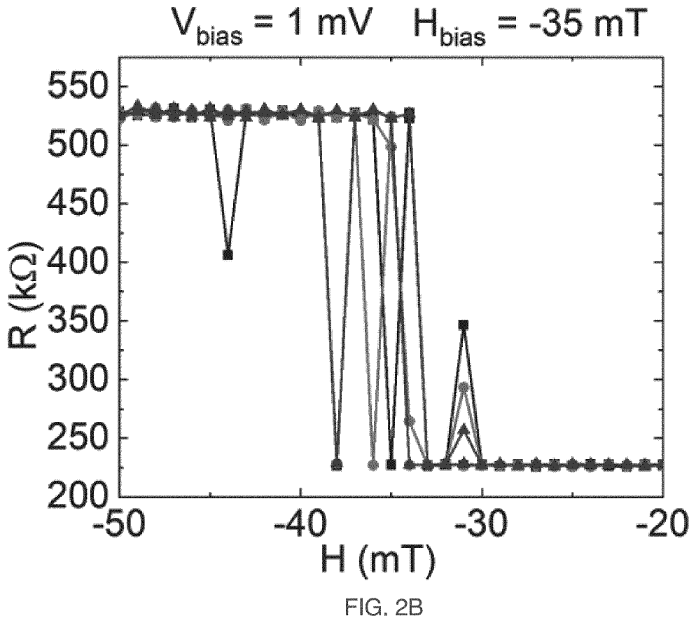

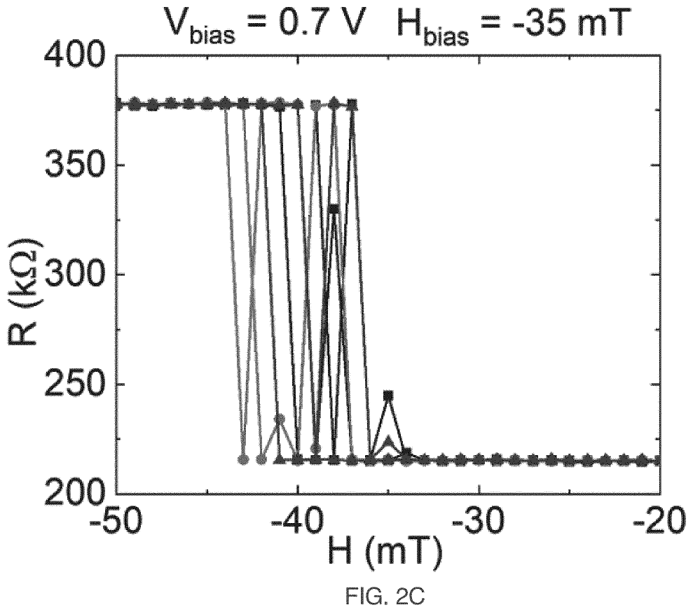

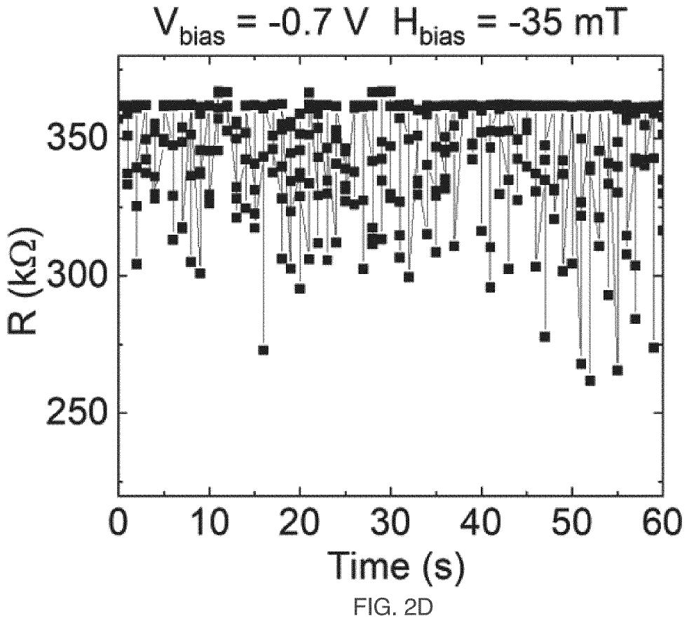

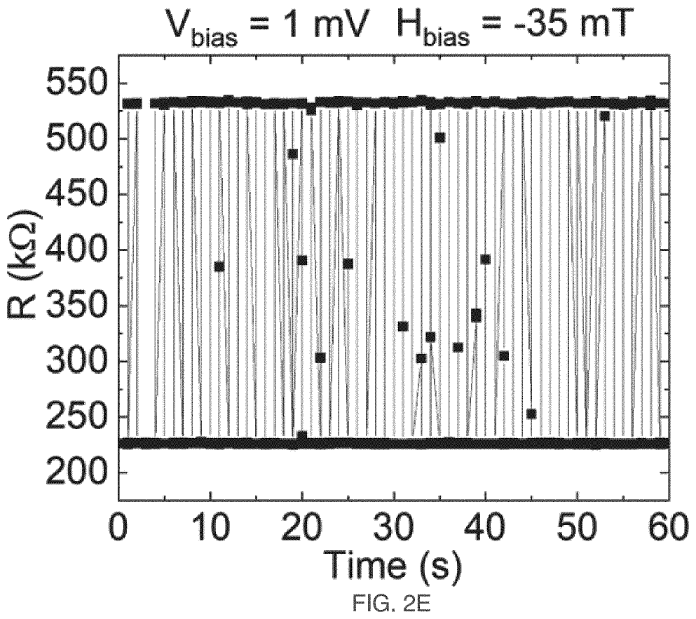

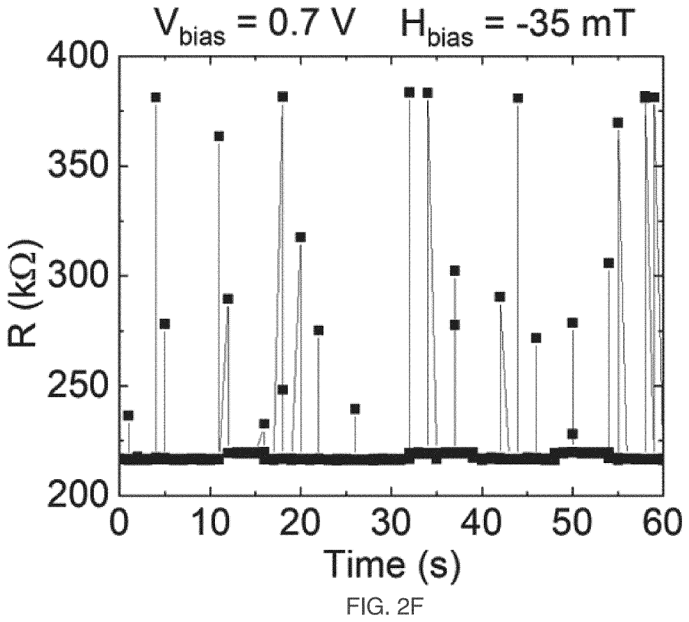

FIGS. 2A, 2B, and 2C illustrate exemplary resistance as a function of external field for an MTJ measured under different DC voltages. FIG. 2A illustrates exemplary resistance at a DC voltage of −1 V, with Vbias=−0.7 V and Hbias=−35 mT. FIG. 2B illustrates exemplary resistance at a DC voltage of 1 mV, with Vbias=1 mV and Hbias=−35 mT. FIG. 2C illustrates exemplary resistance at a DC voltage of 1 V, with Vbias=0.7 V and Hbias=−35 mT. Different lines in each of FIGS. 2A, 2B, and 2C represent different measurement repetitions.

FIGS. 2D, 2E, and 2F illustrate exemplary MTJ resistance oscillations measured as a function of time, under a fixed external magnetic field of H=−350 Oe and different bias voltages. FIG. 2D illustrates exemplary resistance oscillations at a DC voltage of −1 V, with Vbias=−0.7 V and Hbias=−35 mT. FIG. 2E illustrates exemplary resistance oscillations at a DC voltage of 1 mV, with Vbias=1 mV and Hbias=−35 mT. FIG. 2F illustrates exemplary resistance oscillations at a DC voltage of 1 V, with Vbias=0.7 V and Hbias=−35 mT.

Stochastic bit-streams may be generated by measuring the resistance of the MTJs in the time domain under different voltage bias conditions. The resistance of a set of six representative exemplary 50 nm diameter MTJs as a function of external magnetic field, measured under different bias voltages, is illustrated in FIGS. 2A, 2B, and 2C. An offset field of approximately −35 mT was observed in the loop measured at 1 mV, which may be due to the stray field from the uncompensated reference layer. The exemplary MTJ did not show a significant coercivity, consistent with its small energy barrier. Due to the STT effect, the offset field may shift in opposite directions depending on the applied bias voltage. Accordingly, with the external magnetic field fixed at −35 mT, measurements of the resistance under different bias voltages for a period of ˜2 minutes, in intervals of 100 ms, provided ˜1200 data points for each voltage. FIGS. 2D, 2E, and 2F illustrate measurement results under three different bias voltages applied to the exemplary MTJs.

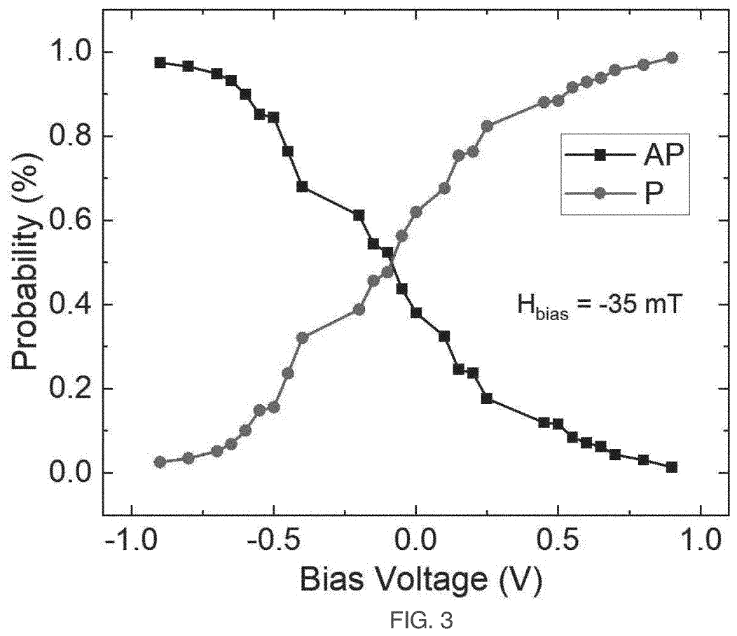

FIG. 3 illustrates exemplary probabilities of 1s and 0s (parallel (P) and antiparallel (AP) states) generated by an exemplary MTJ under different bias voltages. Measurement results show that tunability from >95% AP to >95% P was experimentally achieved by using a voltage less than 1 V, as shown in FIG. 3, corresponding to an ultralow current less than 5 μA (0.25 MA cm⁻²). Using this procedure, exemplary bit-streams were generated representing the entire range of numbers from −1 to 1.

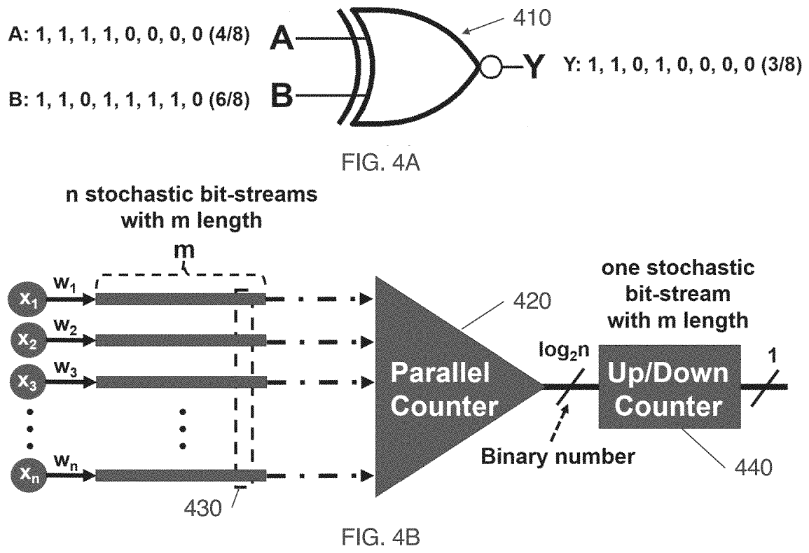

FIG. 4A illustrates exemplary stochastic multiplication using bipolar mapping within the [−1, 1] range. In the SC paradigm, numbers may be represented by a probability of 1s in a bit-stream. In an example, bipolar mapping may map real numbers x within the range of [−1, 1], to bit-streams X, via the relation P(X=1) =(x+1)/2. Using this approach, the key arithmetic operations in an ANN may be implemented as follows.

Multiplication may be implemented with an XNOR gate 410, as illustrated in FIG. 4A. The output of the exemplary XNOR gate may be P(Y)=P(A)·P(B)+P̅(̅A̅)̅·P̅(̅B̅)̅. For bipolar mapping, this may be rewritten as (y+1)/2=[(a+1)/2][(b+1)/2]+[1−(a+1)/2][1−(b+1)/2], which may be reduced to y=ab.

FIG. 4B illustrates an exemplary approximate parallel counter (APC)-based neuron for stochastic dot product and activation functions. The addition and the following activation operation described above with reference to FIG. 4A may be implemented by an APC-based neuron design, for example, as illustrated in FIG. 4B. The multiplication of n inputs x₁, x₂, x₃, . . . , xₙ and weights w₁, w₂, w₃, . . . , wₙ may be performed through XNOR gates 410 as described above, which in experiments has produced n stochastic bit-streams with bit-stream length m as illustrated in FIG. 4B. The addition of the n stochastic bit-streams may be performed by an APC 420, where the sum of 1s in each column 430 may be accumulated. Converting the output from the APC 420, which may be a binary number, into a stochastic bit-stream may be performed by a saturated up/down counter 440 to approximate a hyperbolic tangent function Btanh(n, K, x)≈tanh(x), where K is the number of states for the saturated counter 440 and K=2n in the example described herein. This may be similar to a finite state machine, except that the amount of increase or decrease for the states in each cycle may be determined by the counted number in the APC 420 for each column 430. Given K states in the counter 440, half of the states may generate a 0 output and the other half may generate a 1 output. The output bit-stream may thus be an approximation of the hyperbolic tangent of the result of the dot product.

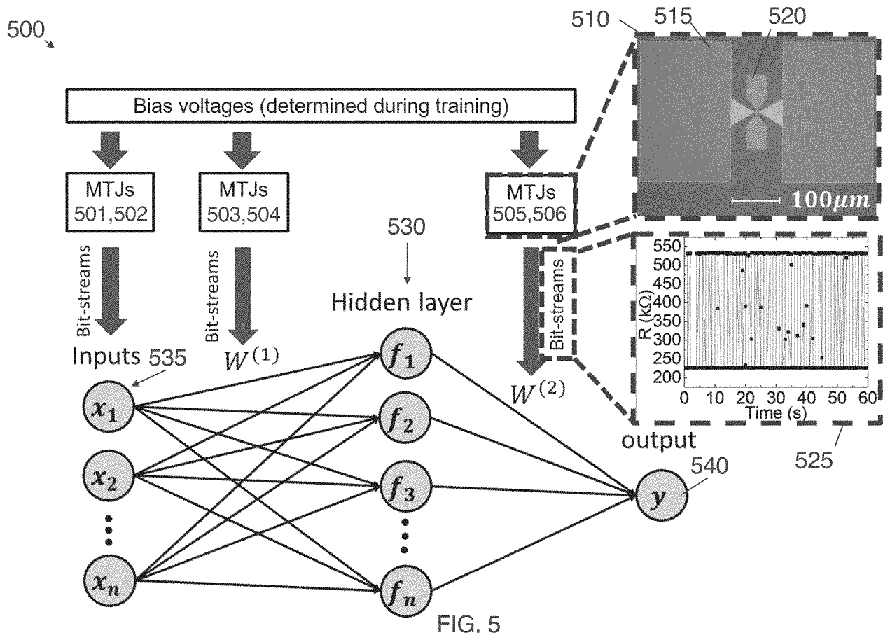

FIG. 5 illustrates an exemplary structure of an SC-ANN 500 using pairs of MTJs (501,502; 503,504; 505,506) for stochastic bit-stream generation. Inset 510 illustrates an exemplary MTJ with bottom electrodes 515 and top electrodes 520. Inset 525 illustrates an exemplary set of measured stochastic data. The exemplary ANN architecture illustrated in FIG. 5 includes one hidden layer 530 having n, for example, 128, neurons f₁, f₂, f₃, . . . , fₙ. The exemplary ANN architecture includes inputs 535 that take in data for processing and an output 540 that outputs processed data. Paths with weights W⁽¹⁾ operate on the data passing between the inputs 535 and the hidden layer 530, and paths with weights W⁽²⁾ operate on the data passing between the hidden layer 530 and the output 540. The inputs 535 may receive data from bit-streams output from the MTJ pair 501, 502. The weights W⁽¹⁾ may receive data from bit-streams output from the MTJ pair 503,504. The weights W⁽²⁾ may receive data from bit-streams output from the MTJ pair 505,506. Each of the MTJs 501-506 may be configured with a bias voltage determined in a training phase.

The inputs 535, for example, x₁, x₂, . . . , xₙ, in an example experiment may include grayscale images of handwritten digits from the MNIST database, whose values are pre-scaled to [0, 1] to be compatible with the stochastic bit-streams. The ANN parameters (weights and biases) may be trained using TensorFlow, on floating point numbers defined by 32 bits, during which L-2 regularization may be employed to ensure the trained weights W⁽¹⁾ and W⁽²⁾ and biases also set within the [−1, 1] range. In example experiments based on these parameters, the resulting training accuracy was 97%.

The SC-ANN 500 may perform an inference process using the stochastic computing approach discussed above, by mapping the inputs 535 and trained parameters to corresponding stochastic bit-streams. The stochastic bit-streams may be generated MTJs 501-506. The MTJs 501-506, for example, may have a diameter of 50 nm. In an exemplary experiment, for each MTJ 501-506, data under ˜30 different bias voltages were obtained, resulting in ˜30 different bit-streams per MTJ 501-506. The products (XNOR) of every pair of MTJs may be used to generate bit-stream sets with deeper number resolution. To cause, facilitate, or ensure that bit-streams involved in each operation are statistically independent of each other, data from different pairs of MTJs may be used to map the values for inputs 535 and weights W⁽¹⁾ and W⁽²⁾ in different layers of the SC-ANN 500. Thus, six MTJs 501-506 in total may be used where each pair of MTJs may be responsible for one of the three statistically independent bit-stream sets used in the SC-ANN 500.

As a consequence of the relatively small number of MTJs that generate bit-streams in the SC-ANN 500, a number of synaptic weights in each layer may still be much larger than the number of sampled bit-streams. To reduce the resulting correlations of bit-streams of the same value in the same layer, one of the MTJs 501-506 may be configured to introduce a random reshuffling mechanism. For example, 512-bit long bit-streams may be divided into eight segments, where each one of the segments is 64-bit long. Each time a number is to be mapped by the corresponding bit-stream, the bit-stream may be rotated and restarted from the i-th segment, where i is a random integer from 0 to 7. To generate the random integers i from 0 to 7 with the same probability each, a bit-stream with 50% probabilities of each of 1s and 0s from one of the MTJs 501-506 may be used. In principle, this exemplary reshuffling mechanism may not be needed or included when the SC-ANN 500 is implemented with a larger number of MTJs than shown in FIG. 5.

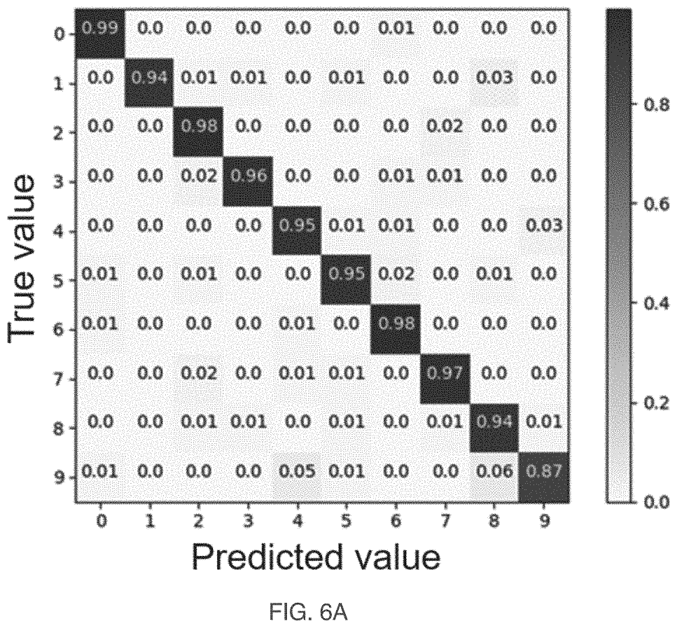

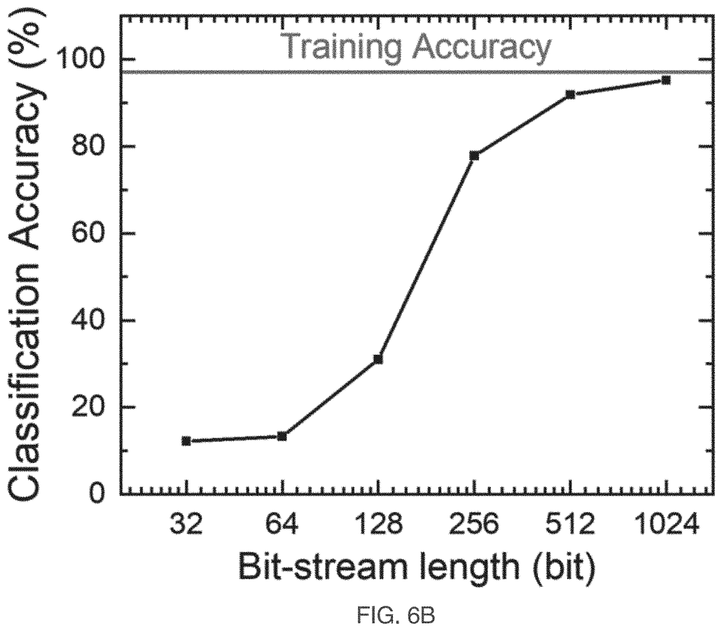

FIG. 6A illustrates an exemplary confusion matrix of the results of an inference operation, using stochastic computing on 1,024-bit long bit-streams. The numbers of correct and incorrect classifications are summarized and normalized for each class. In exemplary experimental results, it can be seen that the ANN successfully classifies the handwritten digits.

FIG. 6B illustrates exemplary classification accuracy achieved on an exemplary inference run with an SC-ANN using different stochastic bit-stream lengths. Based on the results illustrated in FIG. 6B, it is apparent that longer bit-streams provide better classification accuracy, which is understandable because the accuracy of each bit-stream is proportional to its length.

The SC-ANN 500 may be compared to recent works on CMOS and hybrid spintronic-CMOS SC-based neural networks and RNGs in terms of energy dissipation. Specifically, while the circuit design and simulation of a complete SC-ANN 500 are beyond the scope of the present application, here we focus on comparing the performance of the MTJ-based TRNG discussed herein to the RNGs discussed in recent literature.

For a conventional CMOS-based LFSR RNG, the energy per bit may be on the order of ˜10 fJ. Energy dissipation of the TRNG may depend on the retention time τ of the MTJs, which itself may be determined by the energy barrier E_{b}. Although the retention time for an exemplary implementation may be relatively long, the retention time may be reduced by reducing the perpendicular magnetic anisotropy or reducing the diameter of the MTJs in the exemplary implementation. Assuming a reduction of the diameter of exemplary MTJs from 50 nm to 20 nm, a˜6.25× reduction of the free layer volume may be expected, which may result in E_{b}˜2.5 kBT. This may conservatively correspond to a reduction of the retention time (and associated increase of the bit generation rate) to τ˜10 ns. In other exemplary implementations, retention times may be even smaller than 1 ns. Nonetheless, even with τ˜10 ns, the energy per bit may reduce to ˜20 fJ assuming an applied voltage of ˜1 V and device resistance of 500 kΩ, which is comparable to CMOS-only RNGs.

The type of TRNG disclosed herein may also be compared to other implementations of MTJ-based TRNGs. For example, another exemplary implementation of an MTJ-based TRNG may use a digitally controlled circuit to convert the oscillations of a superparamagnetic MTJ into stochastic bit-streams. This other exemplary implementation is qualitatively different from the TRNG discussed above, which is essentially analog (e.g., similar to circuits used for probabilistic (p-) bit generation). Therefore, this other exemplary implementation may represent different tradeoffs and suitable application scenarios. Firstly, an energy dissipation of a pre-charge sense amplifier (PCSA) method used in the other exemplary implementation may be essentially independent of the MTJ device size, in contrast to the approach described above, in which the switching rate may directly affect the energy dissipation. Hence, while the PCSA approach may be expected to provide superior energy efficiency for longer clock cycles (e.g., 150 ns), as clock speed is increased, the analog TRNG approach may achieve similar, if not better, energy efficiency. A second difference may be that in the analog TRNG described above in association with FIGS. 1-6 and the SC-ANN 500, the representation accuracy may be controlled by the length of the bit-streams. For example, a 1,024 bit-long bit-stream may represent all values that are multiples of 1/1024. On the other hand, for the PCSA method, the representation accuracy may be determined by the number of programmable bits in the bit-stream generators, thus determined by the number of transistors and MTJs in the circuit. Hence, for the same representation accuracy, the method described above with reference to FIGS. 1-6 and the SC-ANN 500 may have an overall lower component count than the other exemplary implementation including the PCSA method.

Exemplary MRAM-based SC-ANNs may successfully classify handwritten digits with accuracy up to 95%. The exemplary SC-ANNs disclosed herein with reference to FIGS. 1-6 and the SC-ANN 500 may use experimentally measured stochastic bit-streams generated by 50 nm MTJ-based TRNGs that are tuned by an ultralow electric current (e.g., <5 μA). The accuracy of the classification may be adjusted in real time by changing the length of the bit-streams. Experimental measurements of an exemplary implementation of the SC-ANN 500 illustrate applicability and value for ultra-low-power machine learning in edge, mobile and IoT devices.

In one aspect, a method may be an operation, an instruction, or a function and vice versa. In one aspect, a clause or a claim may be amended to include some or all of the words (e.g., instructions, operations, functions, or components) recited in other one or more clauses, one or more words, one or more sentences, one or more phrases, one or more paragraphs, and/or one or more claims.

To illustrate the interchangeability of hardware and software, items such as the various illustrative blocks, modules, components, methods, operations, instructions, and algorithms have been described generally in terms of their functionality. Whether such functionality is implemented as hardware, software or a combination of hardware and software depends upon the particular application and design constraints imposed on the overall system. Skilled artisans may implement the described functionality in varying ways for each particular application.

As used herein, the phrase “at least one of” preceding a series of items, with the terms “and” or “or” to separate any of the items, modifies the list as a whole, rather than each member of the list (e.g., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No claim element is to be construed under the provisions of 35 U.S.C. § 112, sixth paragraph, unless the element is expressly recited using the phrase “means for” or, in the case of a method claim, the element is recited using the phrase “step for.”

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language claims and to encompass all legal equivalents. Notwithstanding, none of the claims are intended to embrace subject matter that fails to satisfy the requirements of the applicable patent law, nor should they be interpreted in such a way.

### REFERENCES

H. Li, K. Ota, and M. Dong, “Learning IoT in edge: Deep learning for the Internet of Things with edge computing,” IEEE network, vol. 32, no. 1, pp. 96-101, 2018.

C. Chen, A. Seff, A. Kornhauser, and J. Xiao, “Deepdriving: Learning affordance for direct perception in autonomous driving,” in i Proceedings of the IEEE International Conference on Computer Vision, 2015, pp. 2722-2730.

A. E. Sallab, M. Abdou, E. Perot, and S. Yogamani, “Deep reinforcement learning framework for autonomous driving,” Electronic Imaging, vol. 2017, no. 19, pp. 70-76, 2017.

S. Shalev-Shwartz, S. Shammah, and A. Shashua, “Safe, multi-agent, reinforcement learning for autonomous driving,” arXiv preprint arXiv: 1610.03295, 2016.

A. L. Beam and I. S. Kohane, “Big data and machine learning in health care,” Jama, vol. 319, no. 13, pp. 1317-1318, 2018.

C. R. Farrar and K. Worden, Structural health monitoring: a machine learning perspective. John Wiley & Sons, 2012.

D. Ravi, C. Wong, F. Deligianni, M. Berthelot, J. Andreu-Perez, B. Lo, and G.-Z. Yang, “Deep learning for health informatics,” IEEE journal of biomedical and health informatics, vol. 21, no. 1, pp. 4-21, 2016.

N. Y. Hammerla, S. Halloran, and T. Plotz, “Deep, convolutional, and recurrent models for human activity recognition using wearables,” arXiv preprint arXiv: 1604.08880, 2016.

C.-J. Wu, D. Brooks, K. Chen, D. Chen, S. Choudhury, M. Dukhan, K. Hazelwood, E. Isaac, Y. Jia, and B. Jia, “Machine learning at facebook: Understanding inference at the edge,” in 2019 IEEE International Symposium on High Performance Computer Architecture (HPCA), 2019: IEEE, pp. 331-344.

J. Li, A. Ren, Z. Li, C. Ding, B. Yuan, Q. Qiu, and Y. Wang, “Towards acceleration of deep convolutional neural networks using stochastic computing,” in 2017 22nd Asia and South Pacific Design Automation Conference (ASP-DAC), 2017: IEEE, pp. 115-120.

J. Li, Z. Yuan, Z. Li, C. Ding, A. Ren, Q. Qiu, J. Draper, and Y. Wang, “Hardware-driven nonlinear activation for stochastic computing based deep convolutional neural networks,” in 2017 International Joint Conference on Neural Networks (IJCNN), 2017: IEEE, pp. 1230-1236.

A. Ren, Z. Li, C. Ding, Q. Qiu, Y. Wang, J. Li, X. Qian, and B. Yuan, “Sc-dcnn: Highly-scalable deep convolutional neural network using stochastic computing,” ACM SIGPLAN Notices, vol. 52, no. 4, pp. 405-418, 2017.

H. Sim and J. Lee, “A new stochastic computing multiplier with application to deep convolutional neural networks,” in Proceedings of the 54th Annual Design Automation Conference 2017, 2017, pp. 1-6.

B. R. Gaines, “Stochastic computing systems,” in Advances in information systems science: Springer, 1969, pp. 37-172.

B. D. Brown and H. C. Card, “Stochastic neural computation. I. Computational elements,” IEEE Transactions on computers, vol. 50, no. 9, pp. 891-905, 2001.

S. Wang, S. Pal, T. Li, A. Pan, C. Grezes, P. Khalili-Amiri, K. L. Wang, and P. Gupta, “Hybrid VC-MTJ/CMOS non-volatile stochastic logic for efficient computing,” in Design, Automation & Test in Europe Conference & Exhibition (DATE), 2017, 2017: IEEE, pp. 1438-1443.

Y. Lv and J.-P. Wang, “A single magnetic-tunnel-junction stochastic computing unit,” in 2017 IEEE International Electron Devices Meeting (IEDM), 2017: IEEE, pp. 36.2. 1-36.2. 4.

W. A. Borders, A. Z. Pervaiz, S. Fukami, K. Y. Camsari, H. Ohno, and S. Datta, “Integer factorization using stochastic magnetic tunnel junctions,” Nature, vol. 573, no. 7774, pp. 390-393, 2019.

N. Nishimura, T. Hirai, A. Koganei, T. Ikeda, K. Okano, Y. Sekiguchiand Y. Osada, “Magnetic tunnel junction device with perpendicular magnetization films for high-density magnetic random access memory,” Journal of applied physics, vol. 91, no. 8, pp. 5246-5249, 2002.

S. Ikeda, K. Miura, H. Yamamoto, K. Mizunuma, H. Gan, M. Endo, S. Kanai, J. Hayakawa, F. Matsukura, and H. Ohno, “A perpendicular-anisotropy CoFeB—MgO magnetic tunnel junction,” Nature materials, vol. 9, no. 9, pp. 721-724, 2010.

W. J. Gallagher, J. H. Kaufman, S. S. P. Parkin, and R. E. Scheuerlein, “Magnetic memory array using magnetic tunnel junction devices in the memory cells,” ed: Google Patents, 1997.

Y. Lecun, C. Cortes, and C. Burges, “The MNIST Dataset of Handwritten Digits(Images),” ed, 1999.

K. Y. Camsari, S. Salahuddin, and S. Datta, “Implementing p-bits with embedded MTJ,” IEEE Electron Device Letters, vol. 38, no. 12, pp. 1767-1770, 2017.

W. F. Brown Jr, “Thermal fluctuations of a single-domain particle,” Physical review, vol. 130, no. 5, p. 1677, 1963.

A. Fukushima, T. Seki, K. Yakushiji, H. Kubota, H. Imamura, S. Yuasa, and K. Ando, “Spin dice: A scalable truly random number generator based on spintronics,” Applied Physics Express, vol. 7, no. 8, p. 083001, 2014.

G. Fuchs, N. Emley, I. Krivorotov, P. Braganca, E. Ryan, S. Kiselev, J. Sankey, D. Ralph, R. Buhrman, and J. Katine, “Spin-transfer effects in nanoscale magnetic tunnel junctions,” Applied Physics Letters, vol. 85, no. 7, pp. 1205-1207, 2004.

S. Yuasa and D. Djayaprawira, “Giant tunnel magnetoresistance in magnetic tunnel junctions with a crystalline MgO (0 0 1) barrier,” Journal of Physics D: Applied Physics, vol. 40, no. 21, p. R337, 2007.

S. Yuasa, A. Fukushima, T. Nagahama, K. Ando, and Y. Suzuki, “High tunnel magnetoresistance at room temperature in fully epitaxial Fe/MgO/Fe tunnel junctions due to coherent spin-polarized tunneling,” Japanese Journal of Applied Physics, vol. 43, no. 4B, p. L588, 2004.

S. Yuasa, T. Nagahama, A. Fukushima, Y. Suzuki, and K. Ando, “Giant room-temperature magnetoresistance in single-crystal Fe/MgO/Fe magnetic tunnel junctions,” Nature materials, vol. 3, no. 12, pp. 868-871, 2004.

K. Kim, J. Kim, J. Yu, J. Seo, J. Lee, and K. Choi, “Dynamic energy-accuracy trade-off using stochastic computing in deep neural networks,” in Proceedings of the 53rd Annual Design Automation Conference, 2016, pp. 1-6.

M. Abadi, P. Barham, J. Chen, Z. Chen, A. Davis, J. Dean, M. Devin, S. Ghemawat, G. Irving, and M. Isard, “Tensorflow: A system for large-scale machine learning,” in 12th {USENIX} symposium on operating systems design and implementation ({OSDI} 16), 2016, pp. 265-283.

We claim:

1. An artificial neural network (ANN), comprising:
a plurality of magnetic tunnel junction (MTJ) devices configured as true random number generators (TRNGs) to output stochastic bit-streams of random numbers;
a plurality of input nodes configured to receive respective numerical values for processing by the ANN;
a plurality of hidden nodes, at least one of the plurality of hidden nodes in electrical communication with one or more of the plurality of input nodes to receive and output a sum of input values from the one or more of the plurality of input nodes multiplied by a corresponding one of a plurality of first weighting values, each of the plurality of first weighting values corresponding to a respective numerical value from the stochastic bit-streams output by the MTJ devices; and
an output node in electrical communication with one or more of the plurality of hidden nodes to receive and output a sum of hidden values of the one or more of the plurality of hidden nodes multiplied by a corresponding one of a plurality of second weighting values.

2. The ANN of claim 1, wherein numerical values of the random numbers are tuned by electrical current through the MTJ devices via spin-transfer torque.

3. The ANN of claim 1, wherein the MTJ devices comprise a Co/Pt multilayer-based synthetic antiferromagnetic (SAF) structure.

4. The ANN of claim 3, wherein the SAF structure comprises:
a top electrode comprising an electrically conductive material;
a first ferromagnetic layer comprising a CoFeB material disposed below the top electrode;
a tunnel barrier layer comprising a MgO material disposed below the first ferromagnetic layer;
a second ferromagnetic layer comprising a CoFeB material disposed below the tunnel barrier layer;
a coupling layer disposed below the second ferromagnetic layer;
a SAF layer disposed below the coupling layer; and
a bottom electrode comprising an electrically conductive material disposed below the SAF layer.

5. The ANN of claim 1, wherein at least one of the plurality of MTJ devices is configured to introduce a random reshuffling mechanism.

6. The ANN of claim 1, further comprising a digitally controlled circuit configured to convert oscillations of the MTJ devices into the stochastic bit-streams.

7. The ANN of claim 1, further comprising a bias voltage setting circuit configured to set a bias voltage of the MTJ devices according to a training operation of the ANN.

8. The ANN of claim 1, wherein each of the plurality of second weighting values corresponds to a respective numerical value from the stochastic bit-streams output by the MTJ devices.

9. The ANN of claim 1, wherein each of the plurality of input nodes is further configured to multiply the input node's respective numerical value by a corresponding one of a plurality of input weighting values, each of the plurality of input weighting values corresponding to a respective numerical value from the stochastic bit-streams output by the MTJ devices.

10. The ANN of claim 1, wherein the plurality of MTJ devices comprises an electrically coupled pair of MTJ devices.

11. An artificial neural network (ANN), comprising:
a first plurality of magnetic tunnel junction (MTJ) devices configured as true random number generators (TRNGs) to output first stochastic bit-streams of random numbers;
a second plurality of MTJ devices configured as TRNGs to output second stochastic bit-streams of random numbers;
a third plurality of MTJ devices configured as TRNGs to output third stochastic bit-streams of random numbers;
a plurality of input nodes, each of the plurality of input nodes configured to receive a respective numerical value for processing by the ANN and multiply the respective numerical value by a corresponding one of a plurality of input weighting values, each of the plurality of input weighting values corresponding to a respective numerical value from the first stochastic bit-streams output by the first plurality of MJT devices;
a plurality of hidden nodes, one or more of the plurality of hidden nodes in electrical communication with one or more of the plurality of input nodes to receive and output a sum of input values from the one or more of the plurality of input nodes multiplied by a corresponding first weighting value, the corresponding first weighting value also corresponding to a respective numerical value from the second stochastic bit-streams output by the second plurality of MTJ devices; and
an output node in electrical communication with one or more of the plurality of hidden nodes to receive and output a sum of hidden values of the one or more of the plurality of hidden nodes multiplied by a corresponding second weighting value, the corresponding second weighting value corresponding to a respective numerical value from the third stochastic bit-streams output by the third plurality of MTJ devices.

12. The ANN of claim 11, further comprising a bias voltage setting circuit configured to set a bias voltage of one or more of the first MTJ devices, second MTJ devices, or third MTJ devices according to a training operation of the ANN.

13. The ANN of claim 11, further comprising a digitally controlled circuit configured to convert oscillations of one or more of the first MTJ devices, second MTJ devices, or third MTJ devices into the stochastic bit-streams.

14. The ANN of claim 11, wherein numerical values of the random numbers are tuned by electrical current through the MTJ devices via spin-transfer torque.

15. The ANN of claim 11, wherein one or more of the first MTJ devices, second MTJ devices, or third MTJ devices comprise a Co/Pt multilayer-based synthetic antiferromagnetic (SAF) structure.

16. The ANN of claim 15, wherein the SAF structure comprises:
a top electrode comprising an electrically conductive material;
a first ferromagnetic layer comprising a CoFeB material disposed below the top electrode;
a tunnel barrier layer comprising a MgO material disposed below the first ferromagnetic layer;
a second ferromagnetic layer comprising a CoFeB material disposed below the tunnel barrier layer;
a coupling layer disposed below the second ferromagnetic layer;
a SAF layer disposed below the coupling layer; and
a bottom electrode comprising an electrically conductive material disposed below the SAF layer.

17. The ANN of claim 11, wherein at least one of the plurality of MTJ devices is configured to introduce a random reshuffling mechanism.

18. The ANN of claim 11, wherein the first plurality of MTJ devices comprise an electrically coupled pair of MTJ devices.

19. An artificial neural network (ANN), comprising:
a plurality of magnetic tunnel junction (MTJ) devices configured as true random number generators (TRNGs) to output stochastic bit-streams of random numbers;
a plurality of input nodes configured to process respective received numerical values for processing by the ANN; and
an output node configured to:
process one or more of intermediate values resulting from processing by at least the plurality of input nodes to generate a result value, and
output the result value;
wherein the processing includes multiplication by a weighting value corresponding to a respective numerical value from the stochastic bit-streams output by the plurality of MTJ devices.

20. The ANN of claim 19, further comprising a plurality of hidden nodes, one or more of the plurality of hidden nodes in electrical communication with one or more of the plurality of input nodes to process values resulting from processing by at least one or more of the plurality of input nodes.
